(19) United States
(12) Patent Application Publication
(10) Pub. No.: US 2003/0212934 A1
(43) Pub. Date: Nov. 13, 2003

(54) Debug port for on-die dram

(76) Inventor: David Bovitz, Bloomington, MN (US)

Correspondence Address: DICKSTEIN SHAPIRO MORIN & OSHINSKY LLP, 2101 L STREET NW, WASHINGTON, DC, 20037-1526, US

(21) Appl. No.: 10/139,393

(22) Filed: May 7, 2002

(51) Int. Cl. G11C 29/00

(52) U.S. Cl. 714/718

(57) ABSTRACT

A memory subsystem includes a plurality of storage elements and a controller coupled to a switch. In a first mode, the controller controls information transfer to and from the plurality of storage elements. Also coupled to the switch is a debug port controller. The debug port controller can be activated to set the switch to a second mode which permits the debug port controller to control information transfer to and from the plurality of storage element. More specifically, read data can be transferred from the plurality of storage elements to another device, via the switch and a buffer in the debug port controller. Similarly, write data can be transferred to the plurality of storage elements from another device via the buffer in the debug port controller and the switch. The debug port controller may be activated, deactivated, and controlled by setting values in one or more configuration registers.

### FIELD OF INVENTION

The present invention relates to memory testing. More specifically, the present invention relates to an apparatus and method for directly reading and writing DRAM arrays integrated in semiconductor devices even when access to said DRAM arrays is normally controlled by a functional logic of the semiconductor devices.

### BACKGROUND OF THE INVENTION

Electronic memories, such as dynamic random access memories (DRAMs) are often tested to verify proper functionality. For example, many electronic devices, such as personal computers, perform a memory test during device initialization. When an electronic memory is located within a memory device, testing can easily be performed by addressing each memory cell within the memory device and verifying that test patterns can be written to and read from each cell. However, when a memory is integrated into another device, the memory is often managed by the functional logic within that device. In these instances, memory testing becomes problematic because it may be difficult or impossible to address the cells of the memory externally. For example, an integrated memory may not have an external interface for its data, address, and command buses. Or, if an interface is available, the functional logic within the device may not permit another device to directly access the memory.

One device which is a good candidate for incorporating an integrated DRAM is a component of many computer systems known as a north bridge. FIG. 1 illustrates a computer system 100, which may be, for example, an IBM PC compatible system. The computer system 100 includes a CPU 111 which is coupled to a host bus 110. The computer system 100 also includes several additional buses and/or ports, such as a memory bus 120, an AGP port 130, and a PCI bus 140. The north bridge 200 is a semiconductor device containing multiple bus bridges and serves to interface the CPU 111 located on the host bus 110 with the variety of devices which may be attached to the memory bus 120, AGP port 130, and PCI bus 140.

These devices include memory modules 121, which may be attached to the memory bus 120. A graphics card 131 may be attached to the AGP port. Peripheral devices 141 may be attached to the PCI bus 140. A south bridge 500 may also be coupled to the north bridge 200. As shown in FIG. 1, the coupling may be via the PCI bus 140. Alternatively, the north and south bridges 200, 500 may be coupled via a private communication channel. The south bridge 500 may include additional bus bridges, such as a bus bridge to a legacy bus 150 which can be used to couple legacy peripheral devices 151 to the computer system 100. The south bridge 500 may also include certain well known peripherals, such as floppy disk controllers and hard disk controllers.

FIG. 2A is a more detailed block diagram of the north bridge 200. The north bridge 200 performs its bus bridging functions by having a host interface 201 for transferring data to/from the host bus 110, an AGP interface 203 for transferring data to/from the AGP port 130, a PCI interface 204 for transferring data to/from the PCI bus 140, and a memory interface 206 for transferring data to/from the memory bus 120. Since only the memory bus 120 utilizes row and column addresses, the memory bus 120 is also coupled to a memory controller 205 which buffers and reformats addresses and data traffic which passes through the memory interface 206. A switch 202 is coupled to the memory controller 205, and the host 201 interface, AGP interface 203, and PCI interface 204. The switch 202 is used to transfer data, addresses, and commands.

Due to the location of the north bridge 200 in-between the CPU 111 and the memory modules 121, it may be advantageous to integrate a cache memory 300 into the north bridge 200. The storage of the cache may be one or more DRAM arrays 301 integrated into the north bride 200. The cache may be operated by also integrating a functional logic, for example, a cache controller 305, into the north bridge 200. The presence of the functional logic may make it difficult to test the DRAM arrays which make up the storage of the cache memory. Accordingly, there is a need and desire for a method and apparatus to permit testing of the DRAM integrated into a non-memory device.

### SUMMARY OF THE INVENTION

The present invention is directed to an apparatus and method for directly accessing, reading, and writing DRAM integrated into a semiconductor device while bypassing functional logic which ordinarily control access to the DRAM. The DRAM of the present invention is comprised of DRAM arrays coupled to an associated controller to form an array-controller pair. Each array-controller pair is coupled to a switch. The functional logic which controls normal access to the array-controller pairs is also coupled to the switch. However, the switch also includes a debug port which is coupled to a debug port controller. The debug port controller exposes a testing path to the array-controller pairs through the switch. In one preferred embodiment, the device includes a bus bridge to a PCI bus and read/write data can be transferred between the array-controller pairs to the PCI configuration registers of the bus bridge via the debug port controller.

### BRIEF DESCRIPTION OF THE DRAWINGS

The foregoing and other advantages and features of the invention will become more apparent from the detailed description of exemplary embodiments of the invention given below with reference to the accompanying drawings in which:

FIG. 1 is a block diagram of a computer system including a north bridge;

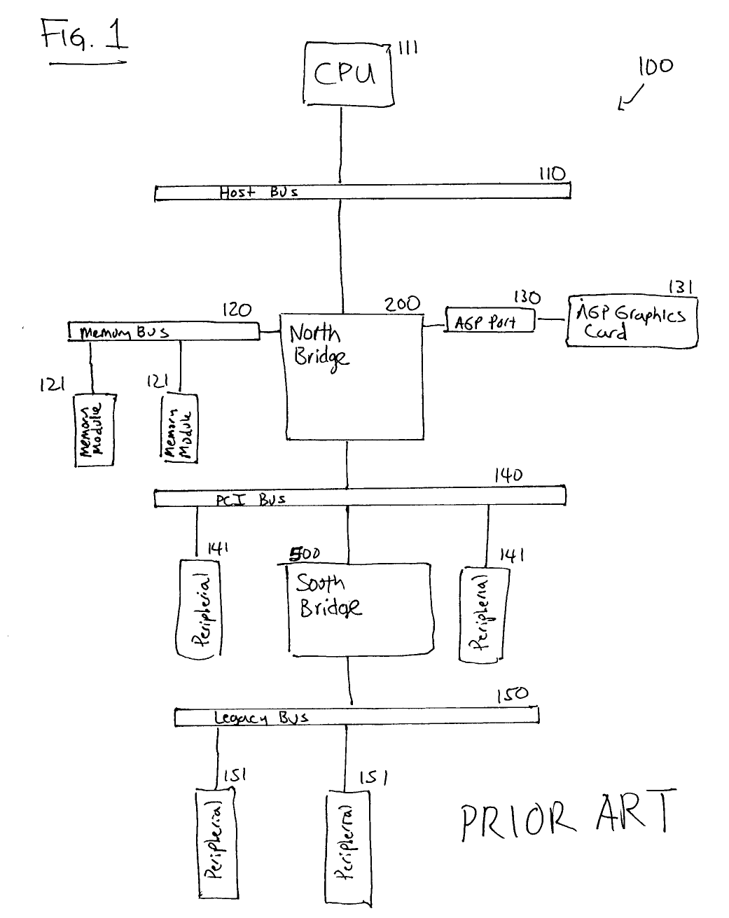

FIG. 2A is a block diagram of the north bridge, including a cache memory;

FIG. 2B is a block diagram of the north bridge, including a cache memory, in accordance with the principles of the present invention;

FIG. 3 is a block diagram of a cache memory, including a debug port controller, in accordance with the principles of the present invention; and

FIG. 4 is a block diagram of the debug port controller in accordance with the principles of the present invention.

### DETAILED DESCRIPTION OF THE INVENTION

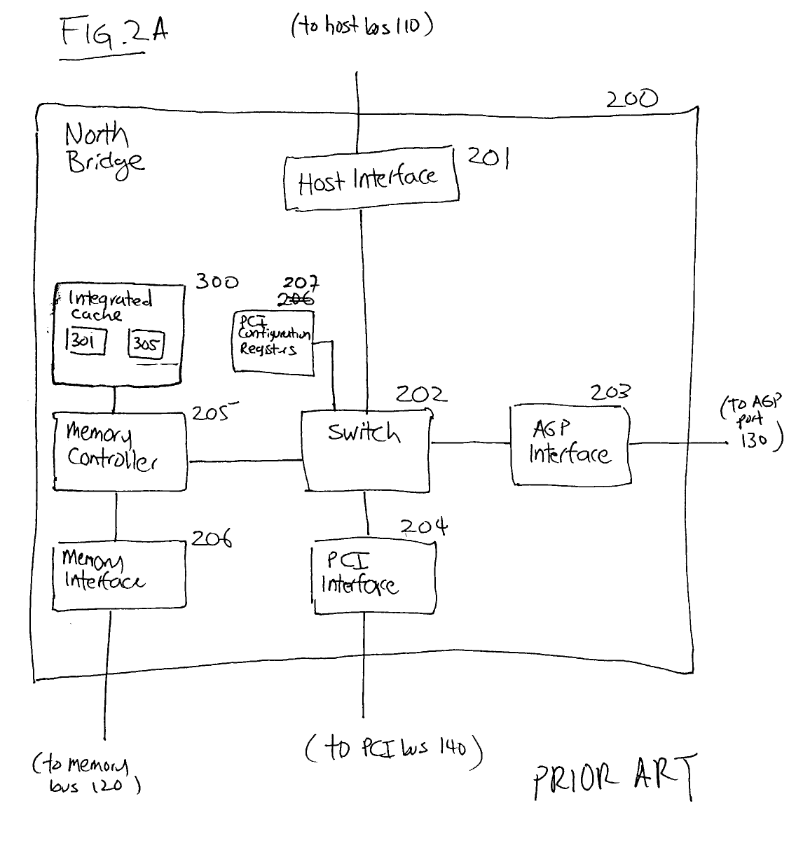

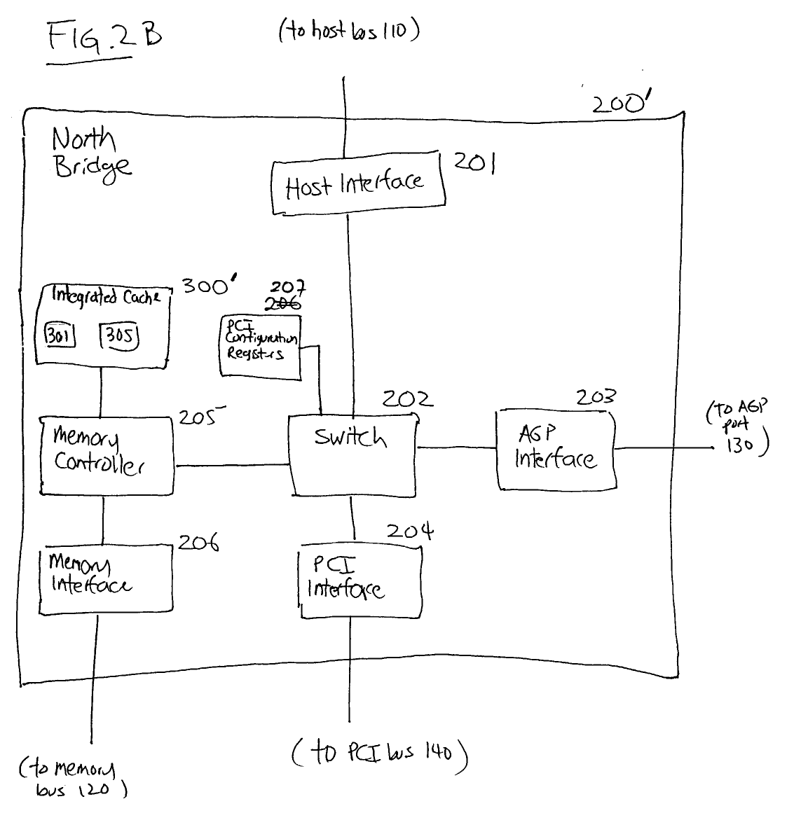

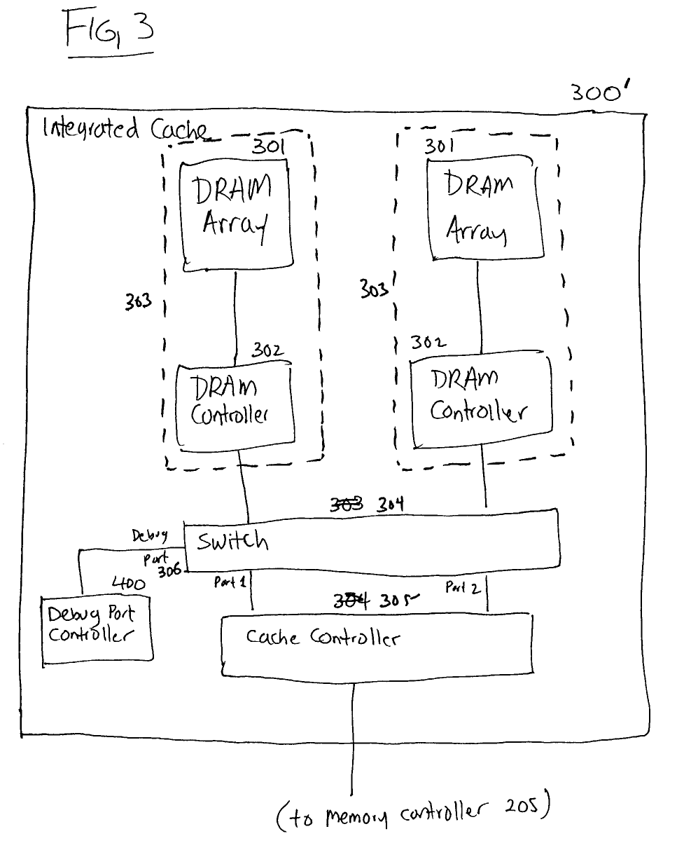

Now referring to the drawings, where like reference numerals designate like elements, there is shown in FIG. 3 a block diagram of a cache memory 300′ integrated into the north bridge 200′ of FIG. 2B. The storage portion of the cache memory 300′ is formed from a plurality of DRAM arrays 301. Each of the DRAM arrays 301 is coupled to its own controller 302, to form an array-controller pair 303. Each array-controller pair 303 is coupled a different port of a switch 304. In the preferred embodiment, the integrated cache includes two array-controller pairs 303, but the number of pairs may be varied, for example, to make the amount of storage in the cache 300′ suitable for a particular computer system. Data is written to and read from the pairs 303 during normal operation of the cache via a cache controller 305, which is also coupled to the switch. In the preferred embodiment, the cache controller is also coupled to two ports of the switch, so that the cache controller can transfer data in parallel to the two pairs 303. However, the number of switch ports used by the cache controller 305 can be varied in order to meet performance or cost goals. The cache controller 305 is also coupled to the memory controller 205 (FIG. 2B). In addition to the ports used to coupled the switch to the cache controller 305 and the array-controller pairs 303, the switch also includes a debug port 306 which is coupled to a debug port controller 400.

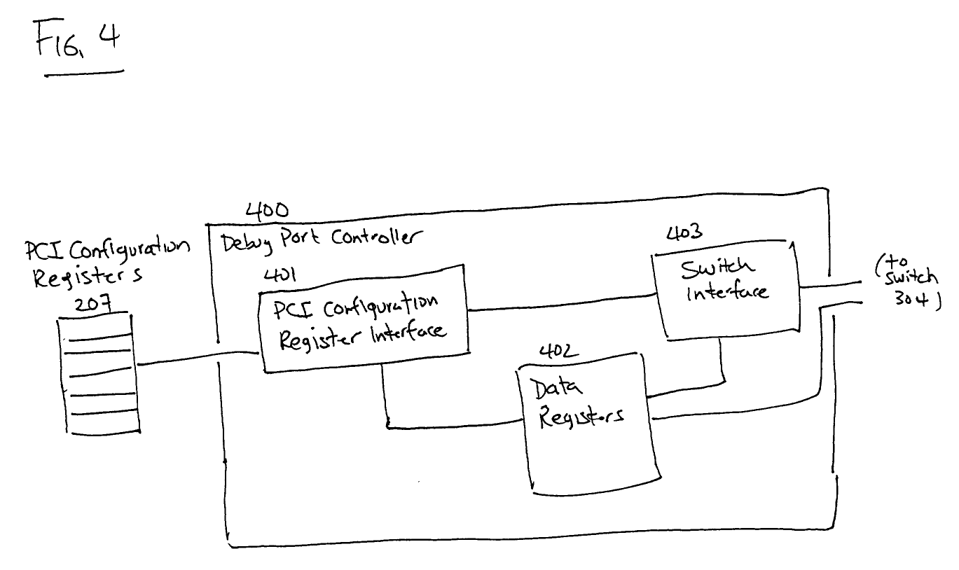

The debug port controller 400 is illustrated in greater detail in FIG. 4, and consists of a PCI Configuration Register Interface 401 for reading/writing data between the PCI configuration registers 207 of the north bridge 200′ and the debug port controller 400. The debug port controller also includes a switch interface 403 for reading/writing data between the switch 304 and the debug port controller. Data being read or written can be temporarily buffered in a set of data registers 402. In the preferred embodiment the data registers 402 store 512 bits organized as four individually addressable 128-bit registers. However, the number of registers and the size of each register may be varied in order to achieve the desired sized buffer. The function of the debug port controller 400 is to provide an alternate access path to the array-controller pairs 303, via the switch 304, without having the traffic of the alternate access path being subject to the processing performed by the functional logic of the device, which in the preferred embodiment is the cache controller 305.

The alternate access path takes advantage of the fact that, as a PCI bus bridge, the north bridge 200′ itself is a PCI device, and as with all PCI devices, is required to support a PCI configuration address space. The PCI configuration address space in a PCI device is comprised of 256 bytes of register based storage and includes a standard portion as well as a device specific portion. In the present invention, a portion of the device specific portion of the north bridge's 200′ PCI configuration address space, specifically seven 32-bit registers, numbered as PCI Configuration Registers 0 through 6, are configured as described below to support information transfer to and from the plurality of pairs 303. Each of the PCI Configuration Registers store one or more values in one or more corresponding bit fields. The following tables, in which bit 31 is defined as the most significant bit and bit 0 is defined as the least significant bit, describes how the PCI Configuration Registers are utilized in the preferred embodiment.

PCI Configuration Register 0

| Start | End | | |
|---|---|---|---|
| Bit | Bit | Name | Description |
| 0 | 0 | WRNR | This bit indicates whether the next trans- |
| | | | action will be a read or a write operation. |
| | | | In the preferred embodiment, a “1” indicates |
| | | | a write and a “0” indicates a read. |
| 1 | 2 | TRANSFER | This 2-bit field specifies the size of the data |
| | | SIZE | transfer to be read or written. A value of |
| | | | “11” corresponds to 512 bits, a value of |
| | | | “01” corresponds to 256 bits, and a value of |
| | | | “00” corresponds to a transfer of 128 bits. |
| | | | The pattern “10” is not used in the preferred |
| | | | embodiment. |
| 3 | 5 | DST_TAG | This 3-bit field indicates which one of the |
| | | | pairs 303, and therefore which one of the |
| | | | DRAM arrays 301 will be written or read. In |
| | | | the preferred embodiment, each pair 303 is |
| | | | assigned a sequential number starting from |
| | | | “0” with a maximum of “8” and the 3-bit |
| | | | field specifies the number of the pair to be |
| | | | read or written. |
| 16 | 31 | DATA | This 16-bit field specifies a data mask used |
| | | MASK | to prevent certain portions of the data from |
| | | | being written during a write transaction. The |
| | | | setting of this field does not affect read |
| | | | operations. |

PCI Configuration Register 1

| Start | End | | |
|---|---|---|---|
| Bit | Bit | Name | Description |
| 0 | 31 | ADDRESS | PCI Configuration Register 1 stores a single |
| | | | 32-bit address field specifiying an address |
| | | | used in the data transfer. I.e., this is the |
| | | | address within the DRAM array 301 |
| | | | specified by the DST_TAG field of PCI |
| | | | Configuration Register 0 where the read or |
| | | | write takes place. |

PCI Configuration Register 2

| Start | End | | |
|---|---|---|---|
| Bit | Bit | Name | Description |
| 1 | 1 | BEGIN | This is a flag set by the CPU 111 to cause |
| | | TRANSFER | the debug port controller 400 to transfer data |
| | | | between the data registers 402 and one of |
| | | | the DRAM arrays 301. When the CPU 111 |
| | | | writes a “1” into this field, the debug port |
| | | | controller 400 initiates the data transfer, |
| | | | which may be a read if WRNR is “0” or a |
| | | | write if WRNR is “1”. When the data trans- |
| | | | fer has been completed, the debug port |
| | | | controller 400 will reset this field to “0.” |
| 3 | 3 | WRITE | This is a flag set by the CPU 111 to indicate |
| | | DATA | when the DATA REGISTER TAG is valid |
| | | READY | for a piece of write data, causing the debug |
| | | | port controller 400 to transfer data. Once |
| | | | data has been transferred, this the debug port |
| | | | controller will clear this bit. |
| 5 | 5 | GET READ | This is a flag set by the CPU 111 to indicate |
| | | DATA | when the DATA REGISTER TAG is valid |
| | | | for a piece of read data, causing the debug |
| | | | port controller 400 to transfer data. Once |
| | | | data has been transferred, this the debug port |
| | | | controller will clear this bit. |
| 8 | 9 | DATA | This 2-bit field contains a value indicating |
| | | REGISTER | which piece of data is to be transferred |
| | | TAG | between the PCI configuration space and the |
| | | | debug port controller. Up to four 128-bit |
| | | | words will be transferred, depending on the |
| | | | value of the TRANSFER SIZE field in PCI |
| | | | Configuration Register 0. |
| 16 | 16 | MASTER | This is a flag set by the CPU 111 to control |
| | | ENABLE | whehther the debug port controller 400 is |
| | | | enabled. A value of “1” enables the debug |
| | | | port controller 400, while a value of “0” |
| | | | disables the debug port controller. |

PCI Configuration Register 3, 4, 5, and 6

| Start | End | | |
|---|---|---|---|
| Bit | Bit | Name | Description |
| 0 | 31 | DATA | PCI Configuration Registers 3, 4, 5, and 6 are |
| | | | used to store the data being read or written. Each |
| | | | of these registers comprise a single bit field which |
| | | | hold different portions of the 128-bit minimum |
| | | | data transfer size. |
| | | | I.e., in register 3, bits 0-31 correspond to data |
| | | | word bits 0-31; in register 4, bits 0-31 |
| | | | correspond to data word bits 32-63; in register |
| | | | 5, bits 0-31 corresponds to data word bits 64-95; |
| | | | and in register 6, bits 0-31 correspond to data |
| | | | word bits 96-127. |

Thus, the processing of writing data to one of the DRAM arrays 301 may take place as follows:

The CPU 111 divides the data to be transferred into 128-bit, 256-bit, or 512-bit portions. If the portion size is larger than 128-bit, each portion is also subdivided into two or four 128-bit subportions. The debug port controller 400 is then enabled by setting the MASTER ENABLE field in PCI Configuration Register 2 to “1.”

Each 128-bit portion or subportion is stored in the DATA fields of PCI Configuration Registers 3, 4, 5, and 6. The DRAM array 301 which is the target of the write is specified in the DEST TAG field of PCI Configuration Register 0. The address within the specified DRAM array 301 where the data will be transferred is also stored in the ADDRESS field of PCI Configuration Register 1. The appropriate transfer size is stored in the TRANSFER SIZE field of PCI Configuration Register 0. If a data mask is desired, it too is stored in the DATA MASK field of PCI Configuration Register 0. Since this is a write transaction, a “1” is stored in the WRNR field of PCI Configuration Register 0.

The CPU 111 then sets the DATA REGISTER TAG of PCI Configuration Register 2 to indicate which one of the registers 402 (i.e., which 128-bit subportion) is receiving the write data. The CPU 111 then sets the WRITE DATA READY field to cause the data stored in PCI Configuration Registers 3, 4, 5, and 6 to be transferred to the specified one of data registers 402. If additional 128-bit subportions require transfer, they may be transferred in sequence to the appropriate one of data registers 402 by repeating the above described steps using the appropriate value for the DATA REGISTER TAG. The CPU 111 can then cause the write data, now stored in data registers 402, to be transferred to the specified DRAM array 301 starting at the specified starting address by setting the BEGIN TRANSFER filed in PCI Configuration Register 2.

Data may be read from a specified one of the DRAM arrays 301 in a manner similar to writing, but in a different order. More specifically, after setting the DST_TAG, TRANSFER SIZE, WRNR, ADDRESS, and MASTER ENABLE fields to appropriate values, 128-, 256-, or 512-bits of data may be transferred from the beginning of the specified address on the specified DRAM array 301 to the data registers 402 by the CPU 111 writing a “1 ” to the BEGIN TRANSFER field. The data can then be transferred, 128-bits at a time, to PCI Configuration Registers 3, 4, 5, and 6's DATA fields by the CPU first setting the DATA REGISTER TAG to select an 128-bit subportion and writing a “1” to the GET READ DATA field.

Thus, the present invention provides a mechanism for a device external to the semiconductor chip integrating a memory, such as a CPU 111, to directly read and write that memory, even if control of memory reads/writes are normally controlled via a functional logic. More specifically, a debug port controller may be coupled, via a debug port on the switch, to any of the memory elements integrated upon the same device. During a normal mode of operation, the functional logic of the semiconductor device operates the memory arrays normally. However, when the debug port controller is activated, the switch is operated in an alternate mode permitting the debug port controller to be coupled to, and perform read/write operations to, any of the memory arrays coupled to the switch. The debug port controller preferably can communicate with another device, such as the CPU 111 or registers 207, in order to communicate commands and data which may be used with read/write operations to test any of the memory arrays.

It should be noted that while an embodiment of the present invention is illustrated and discussed within the context of a cache memory 300′, the principles of the present invention may be used in a variety of other contexts. That is, the cache memory 300′ may be any other type of memory system, while the cache controller 305 may be any other type of functional logic which under normal circumstances controls access to the storage components of the memory system. For example, in FIG. 3, element 300′ may be a regular memory system, and element 305 may be a controller which generates and compares error correction codes.

While the invention has been described in detail in connection with the exemplary embodiment, it should be understood that the invention is not limited to the above disclosed embodiment. Rather, the invention can be modified to incorporate any number of variations, alternations, substitutions, or equivalent arrangements not heretofore described, but which are commensurate with the spirit and scope of the invention. Accordingly, the invention is not limited by the foregoing description or drawings, but is only limited by the scope of the appended claims.

What is claimed as new and desired to be protected by Letters Patent of the United States is:

1. A semiconductor device comprising,
a communications switch having a plurality of normal ports and at least one debug port, said switch being operable in at least a normal mode and a debug mode;
at least one memory array, wherein each of said at least one memory array is coupled to a respective one of said plurality of normal ports and transfers information to and from other devices via the switch;
a logic circuit coupled to at least one of said plurality of normal ports, for managing information transfers to and from said at least one memory array while the switch is in the normal mode;
a debug port controller, coupled to said at least one debug port, for managing information transfers to and from said at least one memory array while the switch is in the debug mode;
wherein said switch is in the normal mode when the debug port controller is not activated and said switch is in the debug mode when the debug port is activated.

2. The semiconductor device of claim 1, wherein said debug port controller comprises,
a switch interface, for communicating with said at least one debug port of said switch;
a storage; and
an interface logic,
wherein said interface logic
activates and deactivates said debug port controller,
controls information transfer to and from said storage, and
controls information transfer to and from said switch.

3. The semiconductor device of claim 2, further comprising:
at least one register;
wherein said interface logic monitors the state of said at least one register to activate and deactivate said debug port controller.

4. The semiconductor device of claim 2, further comprising:
at least one register;
wherein said interface logic monitors the state of said at least one register to transfer information from and to said storage;

5. The semiconductor device of claim 2, further comprising:
a plurality of PCI configuration registers;
wherein said interface logic monitors the states of at least some of said plurality of PCI configuration registers in order to control activation of said debug port controller and information transfer to or from said storage or said switch.

6. A cache memory, comprising:
a communications switch have a plurality of normal ports and at least one debug port, said switch being operable in a normal mode or a debug mode;
a plurality of storage units each comprising a DRAM array coupled to a DRAM controller, each of said storage units being coupled to a respective normal port of said switch;
a cache controller for controlling information transfer to and from said plurality of storage units while said communications switch is in the normal mode, said cache controller coupled to said communications switch via at least one of said normal ports; and
a debug port controller for controlling information transfer to and from said plurality of storage units while said communications switch is in the debug mode, said debug port controller coupled to said communications switch via one of said at least one debug port.

7. The cache memory of claim 6, wherein said debug port controller can be activated and deactivated, and wherein aid debug port controller, when activated, places said communications switch into the debug mode.

8. The cache memory of claim 6, wherein said debug port controller further comprises,
a switch interface, coupled to said communication switch, for transferring information from and to said communications switch;
a interface logic; and
a storage, coupled to said interface logic and said switch interface;
wherein said interface logic
activates and deactivates said debug port controller, and
controls information transfer to and from said storage, and
controls information transfer to and from said switch.

9. The cache memory of claim 6, further comprising:
a plurality of PCI configuration registers;
wherein said interface logic monitors the states of said plurality of PCI configurations to control said debug port controller.

10. The cache memory of claim 9, wherein said control includes controlling activation and deactivation of said debug port controller.

11. The cache memory of claim 9, wherein said control includes controlling information transfer between a CPU and said storage.

12. The cache memory of claim 9, wherein said control includes controlling information transfer between said storage and said switch.

13. A bus bridge, comprising:
a bridge communication switch;
a host interface, coupled to said bridge communication switch, for interfacing said bus bridge to a host bus;
a memory controller, coupled to said bridge communication switch for interfacing said bus bridge to a memory bus;
a memory interface coupled to said memory controller;
a cache coupled to said memory controller, wherein said cache further comprises,
a cache communications switch have a plurality of normal ports and at least one debug port, said switch being operable in a normal mode or a debug mode;
a plurality of storage units each comprising a DRAM array coupled to a DRAM controller, each of said storage units being coupled to a respective normal port of said cache communication switch;
a cache controller for controlling information transfer to and from said plurality of storage units while said cache communications switch is in the normal mode, said cache controller coupled to said cache communications switch via at least one of said normal ports; and
a debug port controller for controlling information transfer to and from said plurality of storage units while said cache communications switch is in the debug mode, said debug port controller coupled to said communications switch via one of said at least one debug port.

14. The bus bridge of claim 13, further comprising:
a PCI interface, coupled to said bridge communication switch; and
a plurality of PCI configuration registers;
wherein a CPU on said host bus can write to the plurality of PCI configuration registers.

15. The bus bridge of claim 14, wherein said debug port controller further comprises,
a cache communication switch interface, coupled to said cache communication switch, for transferring information from and to said cache communications switch;
an interface logic; and
a storage, coupled to said interface logic and said cache communication switch interface;
wherein said interface logic
activates and deactivates said debug port controller,
controls information transfer to and from said storage, and
controls information transfer to and from said switch.

16. The bus bridge of claim 15, wherein said interface logic monitors the states of said plurality of PCI configurations to control said debug port controller.

17. The bus bridge of claim 16, wherein said control includes controlling activation and deactivation of said debug port controller.

18. The bus bridge of claim 16, wherein said control includes controlling information transfer between a CPU and said storage.

19. The bus bridge of claim 16, wherein said control includes controlling information transfer between said storage and said switch.

20. A method for writing a memory subsystem having a plurality of memory arrays, comprising:
activating a debug port controller coupled to a communication switch;
transferring write data to a storage in said debug port controller;
identifying the memory array to be written;
identifying an address within the memory array to be written;
transferring write data from said storage to said identified memory array via said switch.

21. The method of claim 20, wherein said communication switch can operate in a normal mode where another logic controls information transfer to and from said memory subsystem, and a special mode, and wherein said activating sets said communication switch to said special mode.

22. The method of claim 20, wherein said identifying the memory array and identifying an address is performed by setting fields in one or more configuration registers to predetermined values.

23. The method of claim 20, further comprising,
receiving the write data and storing the write data in a buffer; and
wherein said step of transferring write data to a storage transfers the write data from the buffer to the storage.

24. A method of reading a memory subsystem having a plurality of memory arrays, comprising:
activating a debug port controller coupled to a communication switch;
identifying the memory array to be written;
identifying an address within the memory array to be written;
transferring read data to a storage in said debug port controller;
transferring read data from said storage to a buffer outside the memory subsystem.

25. The method of claim 24, wherein said communication switch can operate in a normal mode where another logic controls information transfer to and from said memory subsystem, and a special mode, and wherein said activating sets said communication switch to said special mode.

26. The method of claim 25, wherein said identifying the memory array and identifying an address is performed by setting fields in one or more configuration registers to predetermined values.

27. A memory system comprising:
a switch;
at least one memory array coupled to a first port of said switch;
a first memory controller for accessing said at least one memory array through a second port of said switch; and
a second memory controller for accessing said at least one memory array through a third port of said switch.

28. The memory system of claim 27, wherein said switch is operable such that said second port is operable when said third port is not operable and said third port is operable when said second port is not operable.

29. The memory system of claim 27, wherein said at least one memory array is coupled to said first port of said switch via an array controller.

30. The memory system of claim 27, wherein said first memory controller is a cache controller.

31. The memory system of claim 27, wherein said second memory controller is a debug port controller.

32. The memory system of claim 31, wherein said debug port controller further comprises,
a first interface;
a switch interface; and
at least one data register coupled to said first interface and said switch interface.

33. The memory system of claim 32, wherein said first interface is a PCI configuration register interface.

35. A processing system, comprising:
a processor;
a memory system, coupled to said processor, said memory system further comprising,
a switch;
at least one memory array coupled to a first port of said switch;
a first memory controller for accessing said at least one memory array through a second port of said switch; and
a second memory controller for accessing said at least one memory array through a third port of said switch.

36. The processor system of claim 35, wherein said switch is operable such that said second port is operable when said third port is not operable and said third port is operable when said second port is not operable.

37. The processor system of claim 35, wherein said at least one memory array is coupled to said first port of said switch via an array controller.

38. The processor system of claim 35, wherein said first memory controller is a cache controller.

39. The processor system of claim 35, wherein said second memory controller is a debug port controller.

40. The processor system of claim 39, wherein said debug port controller further comprises,
a first interface;
a switch interface; and
at least one data register coupled to said first interface and said switch interface.

41. The processor system of claim 40, wherein said first interface is a PCI configuration register interface.

42. A system, comprising:
a local bus;
a processor coupled to said local bus;
a bus bridge coupled to said local bus, wherein said bus bridge further comprises,
a bridge communication switch;
a host interface, coupled to said bridge communication switch, for interfacing said bus bridge to a host bus;
a memory controller, coupled to said bridge communication switch for interfacing said bus bridge to a memory bus;
a memory interface coupled to said memory controller;
a cache coupled to said memory controller, wherein said cache further comprises,
a cache communications switch have a plurality of normal ports and at least one debug port, said switch being operable in a normal mode or a debug mode;
a plurality of storage units each comprising a DRAM array coupled to a DRAM controller, each of said storage units being coupled to a respective normal port of said cache communication switch;
a cache controller for controlling information transfer to and from said plurality of storage units while said cache communications switch is in the normal mode, said cache controller coupled to said cache communications switch via at least one of said normal ports; and
a debug port controller for controlling information transfer to and from said plurality of storage units while said cache communications switch is in the debug mode, said debug port controller coupled to said communications switch via one of said at least one debug port.

43. The system of claim 42, further comprising:
a PCI interface, coupled to said bridge communication switch; and
a plurality of PCI configuration registers;
wherein the processor can write to the plurality of PCI configuration registers.

44. The system of claim 43, wherein said debug port controller further comprises,
a cache communication switch interface, coupled to said cache communication switch, for transferring information from and to said cache communications switch;
an interface logic; and
a storage, coupled to said interface logic and said cache communication switch interface;
wherein said interface logic
activates and deactivates said debug port controller,
controls information transfer to and from said storage, and
controls information transfer to and from said switch.

45. The system of claim 44, wherein said interface logic monitors the states of said plurality of PCI configurations to control said debug port controller.

46. The system of claim 45, wherein said control includes controlling activation and deactivation of said debug port controller.

47. The system of claim 45, wherein said control includes controlling information transfer between the processor and said storage.

48. The system of claim 45, wherein said control includes controlling information transfer between said storage and said switch.
